(19) United States
(12) Patent Application Publication
(10) Pub. No.: US 2026/0142629 A1
(43) Pub. Date: May 21, 2026

(54) SETTING VOLTAGE STANDING WAVE RATIO (VSWR) OF DRIVER AMPLIFIER CIRCUIT WITH RESPECT TO A LOAD

(71) Applicant: QUALCOMM Incorporated, San Diego, CA (US)

(72) Inventors: Sreenivasa MALLIA, Bangalore (IN); Ayush MITTAL, Bangalore (IN); Vengatesh VR, Chennai (IN); Krishnaswamy THIAGARAJAN, Bangalore (IN)

(21) Appl. No.: 18/902,367

(22) Filed: Sep. 30, 2024

(51) Int. Cl. H03F 3/24; H03F 1/56; H04B 1/04

(52) U.S. Cl. CPC H03F 3/245; H03F 1/56; H04B 1/0458; H03F 2200/09; H03F 2200/451

(57) ABSTRACT

An apparatus, comprising: a driver amplifier (DA) circuit, comprising: a driver amplifier (DA) including a differential output; a balun including a primary winding and a secondary winding, wherein the differential output of the DA is coupled to the primary winding of the balun, and wherein the secondary winding includes a first portion and a second portion, the second portion being coupled to ground; a first programmable resistor coupled between the first portion of the secondary winding and an output of the DA circuit; and a control circuit configured to adjust a resistance of the first programmable resistor to set a voltage standing wave ratio (VSWR) at a load coupled to the output of the DA circuit.

### FIELD

This disclosure relates to driver amplifiers (DAs), and in particular, to an apparatus and method for setting a voltage standing wave ratio (VSWR) at an output of a DA circuit coupled to a load.

### BACKGROUND

A transmitter may include multiple radio frequency (RF) signal amplification stages. For example, a transmitter may include a driver amplifier (DA) configured to provide a first stage of RF signal amplification followed by a power amplifier (PA) configured to provide a second stage of RF signal amplification. To reduce RF signal losses in the form of reflected signals at the input of the PA, the impedance match between the output of the DA and the input of the PA should be fairly good, such as producing a voltage standing wave ratio (VSWR) at the input of the PA of no more than two (2).

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus, includes: a driver amplifier (DA) circuit, comprising: a driver amplifier (DA) including a differential output; a balun including a primary winding and a secondary winding, wherein the differential output of the DA is coupled to the primary winding of the balun, and wherein the secondary winding includes a first portion and a second portion, the second portion being coupled to ground; a first programmable resistor coupled between the first portion of the secondary winding and an output of the DA circuit; and a control circuit configured to adjust a resistance of the first programmable resistor to set a voltage standing wave ratio (VSWR) at a load coupled to the output of the DA circuit.

Another aspect of the disclosure relates to a method for impedance matching a driver amplifier (DA) circuit to a load coupled to an output of the DA circuit. The method includes adjusting a resistance of a first programmable resistor coupled between a first portion of a secondary winding of a balun and an output, the secondary winding including a second portion coupled to ground, the balun including a primary winding coupled to a differential output of a driver amplifier (DA); and adjusting a resistance of a second programmable resistor coupled between the first portion and the second portion of the balun, wherein adjusting the resistances of the first and second programmable resistors includes setting a voltage standing wave ratio (VSWR) at the load.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example wireless communication system in accordance with an aspect of the disclosure.

FIG. 2 illustrates a block diagram of the example transceiver in accordance with another aspect of the disclosure.

FIG. 3 illustrates a schematic diagram of an example driver amplifier (DA) circuit in accordance with another aspect of the disclosure.

FIG. 4 illustrates a schematic diagram of another example driver amplifier (DA) circuit in accordance with another aspect of the disclosure.

FIG. 5 illustrates a schematic diagram of another example driver amplifier (DA) circuit in accordance with another aspect of the disclosure.

FIG. 6 illustrates a schematic diagram of an example resistor bank in accordance with another aspect of the disclosure.

FIG. 7 illustrates a schematic diagram of another example driver amplifier (DA) circuit in accordance with another aspect of the disclosure.

FIG. 8 illustrates a graph of voltage standing wave ratio (VSWR) versus resistor bank code in accordance with another aspect of the disclosure.

FIG. 9 illustrates a flow diagram of an example method of impedance matching an output of a driver amplifier (DA) circuit with an output load in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

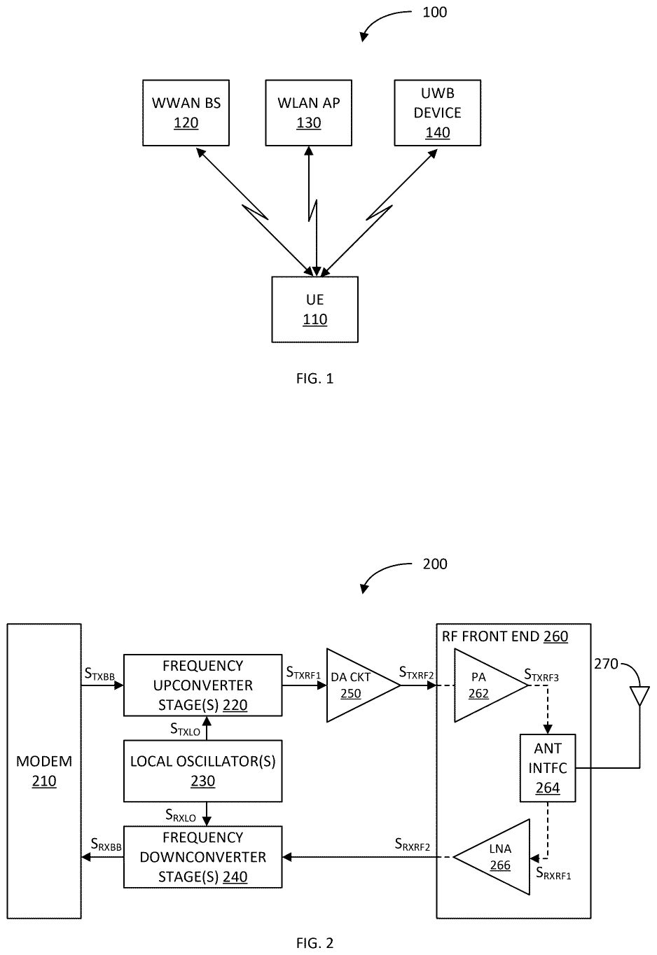

FIG. 1 illustrates a block diagram of an example wireless communication system 100 in accordance with another aspect of the disclosure. The wireless communication system 100 includes a user equipment (UE) 110, a wireless wide area network (WWAN) base station (BS) 120, a wireless local area network (WLAN) access point (AP)130, and a second ultra wideband (UWB) device 140. The UE 110 may include a transceiver for wirelessly communicating with the WWAN BS 120, WLAN BS 530, and/or UWB device 140 in accordance with different protocols (e.g., Fifth Generation (5G) or Sixth Generation (6G), New Radio (NR) protocol for WWAN communication, WiFi for WLAN communication, and UWB protocol for vehicle keyless access). Each of the protocols may facilitate wireless communication using different communication frequency bands.

FIG. 2 illustrates a block diagram of an example transceiver 200 in accordance with another aspect of the disclosure. The transceiver 200 may be implemented in the UE 110 for wirelessly communicating with any of the WWAN BS 120, WLAN AP 130, UWB device 140, and/or other.

The transceiver 200 includes a modem 210, one or more frequency upconverting stage(s) 220, one or more local oscillators 230, one or more frequency downconverting stage(s) 240, a driver amplifier (DA) circuit 250, a radio frequency (RF) front end 260, and an antenna 270 (e.g., an antenna array). The RF front end 260, in turn, includes a power amplifier (PA) 262, an antenna interface 264 (e.g., duplexer, diplexer, or other type of antenna interface), and a low noise amplifier (LNA) 268.

With regard to signal transmission, the modem 210 is configured to generate a transmit baseband signal S_{TXBB}. The one or more frequency upconverting stage(s) 220 is configured to frequency upconvert the transmit baseband signal S_{TXBB} (e.g., from baseband (BB) to radio frequency (RF) directly or via one or more intermediate frequencies (IFs)) using one or more transmit local oscillator signal(s) S_{TXLO} generated by the one or more local oscillators 230 to generate a first-stage transmit RF signal S_{TXRF1}. The DA circuit 250 is configured to amplify the first-stage transmit RF signal S_{TXRX1} to generate a second-stage transmit RF signal S_{TXRX2}. The PA 262 is configured to amplify the second-stage transmit RF signal S_{TXRF2} to generate a third-stage or output transmit RF signal S_{TXRF3}. The output RF signal S_{TXRF3} is provided to the antenna 270 via the antenna interface 264. The antenna 270 is configured to wirelessly radiate the output RF signal S_{TXRF3} for transmission to a remote device, such as one or more of the WWAN BS 120, WLAN AP 130, or UWB device 140.

With regard to signal reception, the antenna 270 may wirelessly sense/pickup a received RF signal S_{RXRF1} from a remote device, such as one or more of the WWAN BS 120, WLAN AP 130, or UWB device 140. The LNA 266 is configured to receive the RF signal S_{RXRF1} via the antenna interface 264. The LNA 266 is configured to amplify the received RF signal S_{RXRF1} to generate an amplified received RF signal S_{RXRF2}. The one or more frequency downconverting stage(s) 240 is configured to frequency downconvert the received RF signal S_{RXRF2} (e.g., from RF to BB directly or via one or more IFs) using one or more received local oscillator signals S_{RXLO} generated by the one or more local oscillators 230 to generate a received BB signal S_{RXBB}. The modem 210 may receive and process the BB signal S_{RXBB} to extract and/or recover information or data therein.

The components of the transceiver 200 may be implemented as separate components or integrated into one or more integrated circuits (ICs) in various different manners. For example, the modem 210 may be integrated with the frequency converting components 220, 230, and 240, and the DA circuit 250 into a single IC separate from the RF front end 260.

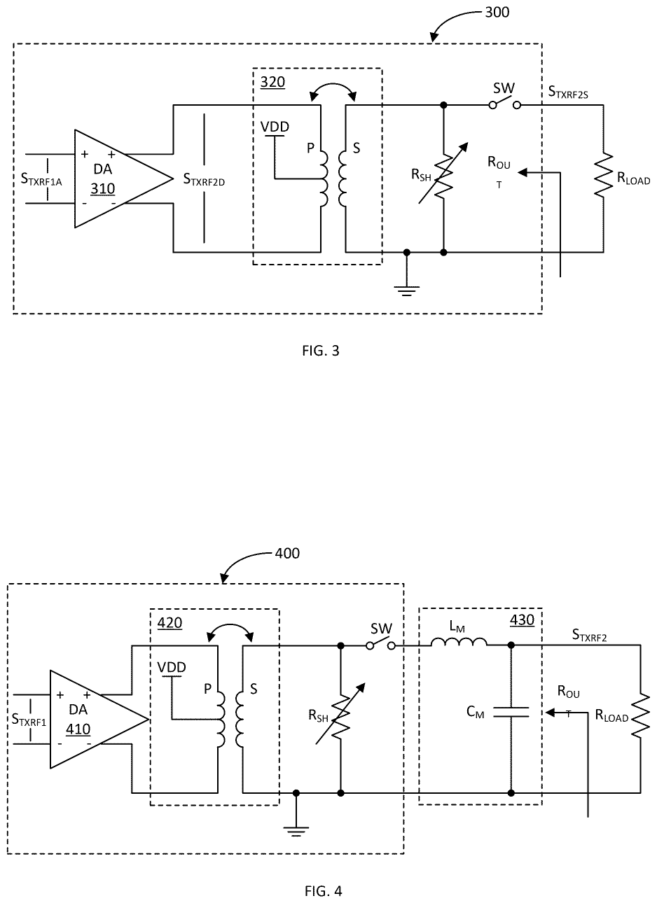

FIG. 3 illustrates a block/schematic diagram of an example driver amplifier (DA) circuit 300 in accordance with another aspect of the disclosure. The DA circuit 300 includes a driver amplifier (DA) 310, a transformer or balun 320, a programmable (variable) shunt resistor R_{SH}, and an output switching device (SW) (e.g., a field effect transistor (FET)). A load R_{LOAD}, such as a power amplifier (PA) (e.g., such as PA 262), represented by its input impedance of 50Ω, may be coupled to an output of the DA circuit 300.

The DA 310 includes a differential input +/−configured to receive an input differential transmit RF signal S_{TXRX1}. The DA 310 includes a differential output +/−coupled to (e.g., both ends of) a primary winding (P) of the balun 320. The primary winding (P) may include a center tap coupled to an upper voltage rail Vdd for routing a supply voltage to the DA 310 via the primary winding (P) and the differential output +/−of the DA 310. The DA 310 is configured to amplify the input differential transmit RF signal S_{TXRX1} to generate an output differential RF signal S_{TXRX2D}.

The balun 320 is configured to convert the output differential RF signal S_{TXRF2D} of the DA 310 into an output single-ended RF signal S_{TXRF2S} at an upper (e.g., non-grounded) portion of a secondary winding(S) of the balun 320, the lower portion being coupled to ground. The programmable shunt resistor R_{SH} is coupled between the upper and lower portions of the secondary winding(S) of the balun 320 (e.g., in parallel with the secondary winding (S)). The output switching device SW, which may be optional, is coupled between the upper portion of the secondary winding(S) and the load R_{LOAD} (e.g., PA 262). The load R_{LOAD} may be coupled between the output switching device SW and ground. The output single-ended RF signal S_{TXRF2S} may be provided to the load R_{LOAD} via the (closed or turned-on) output switching device (SW). The load R_{LOAD} may have an impedance of substantially 50 Ohms (Ω).

The impedance looking into the output of the of the DA circuit 300 may be represented as R_{OUT}. For certain frequency bands (e.g., bands within 600-900 MHz), the output impedance R_{OUT} of the DA circuit 300 may be higher than 50Ω. A requirement may be imposed on the DA circuit 300 that the impedance mismatch between its output impedance R_{OUT} and the impedance 50Ω of the load R_{LOAD} (e.g., input of the PA 262) should produce a voltage standing wave ratio VSWR at the load R_{LOAD} of no more than two (2). Given such requirement, the acceptable range for the output impedance R_{OUT} of the DA circuit 300 may be between 25Ω and 100Ω.

In some implementations of the DA circuit 300, the output impedance R_{OUT} of the DA circuit 300 may be higher than 100Ω for certain operating communication frequency bands (e.g., 600-900 mega Hertz (MHz)). In such case, the impedance mismatch due to the output impedance R_{OUT} being higher than 100Ω may be addressed by the programmable shunt resistor R_{SH}, which may be programmed to lower the output impedance R_{OUT} so that it is within the specification range of 25Ω to 100Ω.

However, there may be a need to operate the DA circuit 300 in other frequency bands (e.g., a communication frequency band situated around 400 MHz) where its output impedance R_{OUT} (e.g., <25Ω) is lower than the acceptable impedance range to meet the specified VSWR range (e.g., VSWR≤two (2)). In such situation, the programmable shunt resistor R_{SH} may not be useful as it may only reduce the output impedance R_{OUT}.

Accordingly, to improve the impedance match between the output impedance R_{OUT} of the DA circuit 300 and the load R_{LOAD}, two approaches may be used. The DA circuit 300 may be redesigned to meet the output impedance R_{OUT} requirements for all operating frequency bands from, for example, 400 to 900 MHz. But such approach may not be desirable as the current design for the DA circuit 300 may have been verified and relied upon for a number of years, and a redesign of the DA circuit 300 may degrade performance and put the silicon (IC) at risk.

FIG. 4 illustrates a block/schematic diagram of another example driver amplifier (DA) circuit 400 in accordance with another aspect of the disclosure. In this example, the DA circuit 400 may address the situation where its output impedance R_{OUT} may be lower than the acceptable output impedance range. The DA circuit 400 is similar to that of DA circuit 300 including many of the same/similar elements as indicated by the same labels, and reference numbers with the most significant digit being a “4” instead of a “3”.

A difference between DA circuits 400 and 300 is that an impedance matching circuit 430 is coupled between the DA circuit 400 and the load R_{LOAD}, whereas DA circuit 400 may be directly coupled to the load R_{LOAD} as discussed above. In this example, the impedance matching circuit 430 includes a series inductor L_{M} and a shunt capacitor C_{M}. More specifically, the series inductor L_{M} is coupled between the output switching device SW and the load R_{LOAD}. And, the shunt capacitor C_{M} is coupled in parallel with the load R_{LOAD}. The inductance of the inductor L_{M} and capacitance of the shunt capacitor C_{M} may be set to increase the output impedance R_{OUT} of the DA circuit 400 to be within the acceptable impedance range for the band of interest (e.g., 400 MHz). However, this approach may also not be that desirable because it adds components (e.g., L_{M} and C_{M}) to the bill of materials (BOM) for customers of the DA circuit 400.

FIG. 5 illustrates a block/schematic diagram of an example driver amplifier (DA) circuit 500 in accordance with another aspect of the invention. The DA circuit 500 includes similar/same elements as DA circuit 300 including similar/same components as indicated by the same labels, and reference numbers with the most significant digit being a “5” instead of a “3”.

The DA circuit 500 further includes a programmable (variable) series resistor R_{SR} coupled between the upper portion of the secondary winding(S) of the balun 520 and the output switching device SW (if present) or, more generally, between the upper portion of the secondary winding(S) and the load R_{LOAD}. Thus, if the output impedance R_{OUT} of the DA circuit 500 for a certain operating frequency band is lower than the acceptable output impedance range (e.g., <25Ω) to meet the VSWR requirement at the load R_{LOAD} (e.g., VSWR≤2), the programmable series resistor R_{SR} may be increased so as to set the output impedance R_{OUT} of the DA circuit 500 within specification (e.g., within 25Ω to 100Ω).

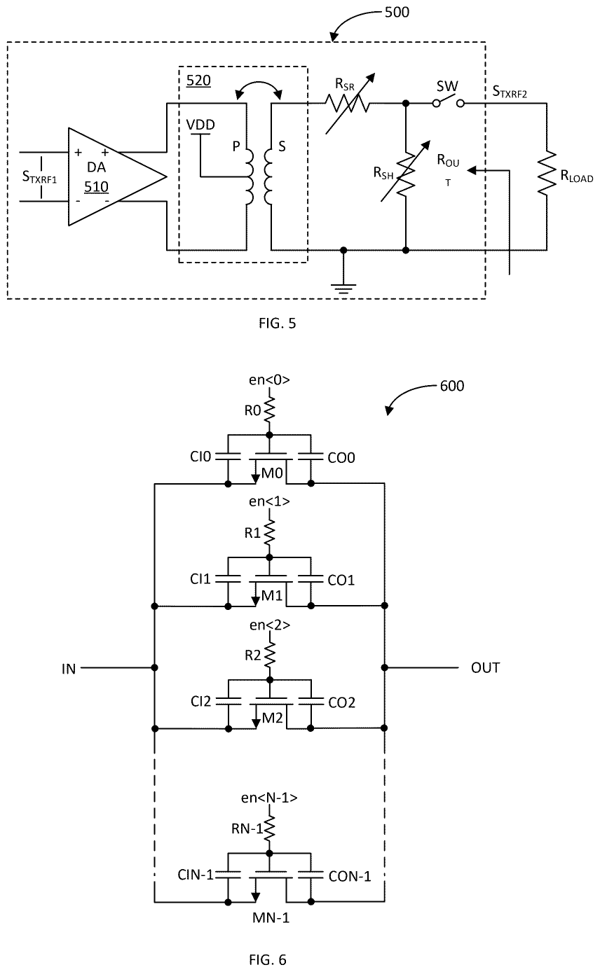

FIG. 6 illustrates a schematic diagram of an example programmable (variable) series resistor R_{SR} 600 in accordance with another aspect of the disclosure. The programmable series resistor R_{SR} may be implemented as a switch bank resistor. In this regard, the programmable series resistor R_{SR} includes a set of switching devices M0 to MN−1 (e.g., field effect transistors (FETs), or more specifically, n-channel FETs (NFETs)) coupled in parallel between an input and an output, where N is an integer (e.g., eight (8), as in an 8-bit control). The input may be coupled to the upper portion of the secondary winding(S) of the balun 520 and the output may be coupled to the output switching device SW or load R_{LOAD} (e.g., the load side of the programmable series resistor R_{SR}).

The FET-based switching devices M0 to MN−1 may be, size-wise, binary-weighted or weighted in other manners. For example, in the case of N=8, the FET M0 may be sized (normalized) to 1×, FET M1 may be sized to 2×, FET M2 may be sized to 4×, FET M3 may be sized to 8× . . . M7 may be sized to 128×. The FETs M0 to MN−1 include gate terminals configured to receive control signal en<0> to en<n−1>, respectively. Each of the FETs M0 to M7 includes a source/drain terminal coupled to the input and a drain/source terminal coupled to the output.

The FET-based switching devices M0 to MN−1 may be implemented as bootstrapping FET-based switching devices, including input bootstrapping capacitors CI0 to CIN−1 coupled between the input of the programmable series resistor R_{SR} and gates of the FET-based switching devices M0 to MN−1, and output bootstrapping capacitors CO0 to CON−1 coupled between the output of the programmable series resistor R_{SR} and the gates of the FET-based switching devices M0 to MN−1, respectively. The FET-based switching devices M0 to MN−1 further includes a set of resistors R0 to RN−1 via which the gate terminals of the FET-based switching devices M0 to MN−1 receive the control signal en<0> to en<n−1>, respectively. The bootstrapping configuration of the FET-based switching devices may be required to maintain the FET-based switching device ON when the voltages at the input and output of the programmable series resistor R_{SR} have large swings (e.g., at or greater than the threshold voltages of the FETs M0-MN−1).

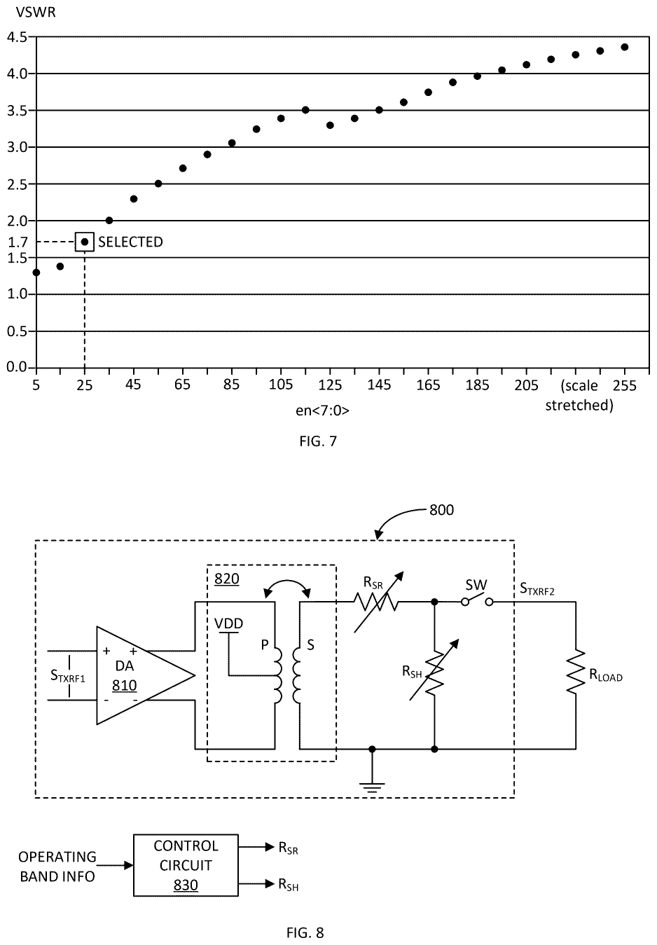

FIG. 7 illustrates a graph of the VSWR associated with the output impedance R_{OUT} of the DA circuit 400 versus resistance of the programmable series resistor R_{SR} in terms of control signal en<N−1:0> in accordance with another aspect of the disclosure. The horizontal axis of the graph represents the value of the control signal en<7:0> from five (5) to 255. The vertical axis represents the VSWR associated with the output impedance R_{OUT} of the DA circuit 400 from 0.0 to 4.5.

The resistance calibration procedure of the programmable series resistor R_{SR} may begin with setting the programmable series resistor R_{SR} to the least resistance including turning on all of the switching devices M0 to M7 by setting the control signal en<7:0> to 255. At en<7:0>=255, the VSWR may be about 4.4 (e.g., which may be greater than the acceptable VSWR range of ≤2.0).

Continuing with the calibration procedure, the resistance of the programmable series resistor R_{SR} may be progressively increased until a desired VSWR as well as signal attenuation may be achieved. That is, increasing the resistance of the programmable series resistor R_{SR} may improve the VSWR, but it also increases the attenuation of the output signal S_{TXRF2} of the DA circuit 500. In this example, this may coincide with the control signal en<7:0> being set to 25 to achieve a VSWR of 1.7. Improving the VSWR further to 1.4 or 1.3 may be achieved by setting the control signal en<7:0> to 15 or five (5), respectively. However, as mentioned, the higher resistance for the programmable series resistor R_{SR} also results in an increase in the attenuation of the output signal S_{TXRF2} of the DA circuit 500. Thus, a tradeoff may exist between VSWR and attenuation.

FIG. 8 illustrates a block/schematic diagram of an example driver amplifier (DA) circuit 800 in accordance with another aspect of the invention. The DA circuit 800 includes the same elements as DA circuit 500 (same labels with same reference numbers but starts with an “8” in DA circuit 800). The DA circuit 800 includes or is associated with a control circuit 830 (e.g., as part of a transceiver control circuit). The control circuit 830 is configured to control the resistance of the programmable series and shunt resistors R_{SR} and R_{SH} based on the current operating frequency band.

For example, if the current operating frequency band is within a frequency range (e.g., 600-900 MHz) that produces an output impedance R_{OUT} of the DA circuit 800 that is higher than the acceptable impedance range for VSWR or impedance matching purpose, the control circuit 830 sets the programmable shunt resistor R_{SH} to a resistance (e.g., between its minimum and maximum resistance) that results in the output impedance R_{OUT} being within specification (e.g., 25Ω to 100Ω), while setting the programmable series resistor R_{SR} to its minimum resistance (e.g., en<7:0>=255).

Similarly, if the current operating band is within a frequency range (e.g., around 400 MHz) that produces an output impedance R_{OUT} of the DA circuit 800 that is lower than the acceptable impedance range for VSWR or impedance matching purpose, the control circuit 830 sets the programmable series resistor R_{SR} to a resistance that results in the output impedance R_{OUT} being within specification (e.g., 25Ω to 100Ω), while setting the programmable shunt resistor R_{SH} to its maximum resistance. In both cases, the resistance of the programmable shunt resistor R_{SH} is greater than the resistance of the programmable series resistor R_{SR}.

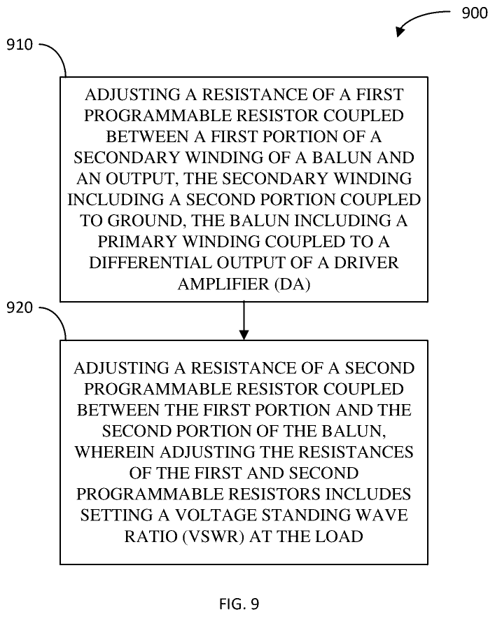

FIG. 9 illustrates a flow diagram of an example method 900 of impedance matching a driver amplifier (DA) circuit to a load in accordance with another aspect of the disclosure. The method 900 includes adjusting a resistance of a first programmable resistor coupled between a first portion of a secondary winding of a balun and an output, the secondary winding including a second portion coupled to ground, the balun including a primary winding coupled to a differential output of a driver amplifier (DA) (block 910).

The method 900 further includes adjusting a resistance of a second programmable resistor coupled between the first portion and the second portion of the balun, wherein adjusting the resistances of the first and second programmable resistors includes setting a voltage standing wave ratio (VSWR) at the load (block 920).

The following provides an overview of aspects of the present disclosure:

Aspect 1: An apparatus, comprising: a driver amplifier (DA) circuit, comprising: a driver amplifier (DA) including a differential output; a balun including a primary winding and a secondary winding, wherein the differential output of the DA is coupled to the primary winding of the balun, and wherein the secondary winding includes a first portion and a second portion, the second portion being coupled to ground; a first programmable resistor coupled between the first portion of the secondary winding and an output of the DA circuit; and a control circuit configured to adjust a resistance of the first programmable resistor to set a voltage standing wave ratio (VSWR) at a load coupled to the output of the DA circuit.

Aspect 2: The apparatus of aspect 1, wherein the control circuit is configured to adjust a resistance of the first programmable resistor to set the VSWR to within a range of two (2) or less.

Aspect 3: The apparatus of aspect 1 or 2, wherein the control circuit is configured to adjust the resistance of the first programmable resistor based on information regarding an operating frequency band of the DA circuit.

Aspect 4: The apparatus of any one of aspects 1-3, further comprising a second programmable resistor coupled between the first portion and the second portion of the secondary winding of the balun.

Aspect 5: The apparatus of aspect 4, wherein the control circuit is configured to adjust a resistance of the second programmable resistor to set the VSWR.

Aspect 6: The apparatus of aspect 5, wherein the control circuit is configured to adjust the resistances of the first and second programmable resistors to set the VSWR.

Aspect 7: The apparatus of aspect 5 or 6, wherein the control circuit is configured to adjust the resistances of the first and second programmable resistors based on information regarding an operating frequency band of the DA circuit.

Aspect 8: The apparatus of any one of aspects 5-7, wherein the control circuit is configured to adjust the resistance of the second programmable resistor to be greater than the resistance of the first programmable resistor.

Aspect 9: The apparatus of any one of aspects 5-8, wherein, in a first configuration, the control circuit is configured to: adjust the resistance of the first programmable resistor to be between a minimum resistance and a maximum resistance for the first programmable resistor; and adjust the resistance of the second programmable resistor to a maximum resistance for the second programmable resistor.

Aspect 10: The apparatus of aspect 9, wherein, in a second configuration, the control circuit is configured to: adjust the resistance of the first programmable resistor to be between at the minimum resistance for the first programmable resistor; and adjust the resistance of the second programmable resistor to be between a minimum resistance and the maximum resistance for the second programmable resistor.

Aspect 11: The apparatus of any one of aspects 1-10, wherein the first programmable resistor comprises a set of switching devices coupled in parallel between the first portion of the secondary winding of the balun and the output of the DA circuit, wherein the control circuit is coupled to the set of switching devices.

Aspect 12: The apparatus of aspect 11, wherein the set of switching devices comprises a set of field effect transistors (FETs) including a set of drain/source terminals coupled to the first portion of the secondary winding of the balun, a set of source/drain terminals coupled to the output of the DA circuit, and a set of gate terminals coupled to the control circuit, respectively.

Aspect 13: The apparatus of aspect 12, wherein the set of switching devices comprises: a first set of capacitors coupled between the set of drain/source terminals and the set of gate terminals of the set of FETs, respectively; a second set of capacitors coupled between the set of source/drain terminals and the set of gate terminals of the set of FETs, respectively; and a set of resistors coupled between the set of gate terminals and the control circuit, respectively.

Aspect 14: The apparatus of any one of aspects 1-13, wherein the load comprises a power amplifier (PA).

Aspect 15: The apparatus of any one of aspects 1-14, wherein the load has an impedance of substantially 50 Ohms.

Aspect 16: A method for impedance matching a driver amplifier (DA) circuit to a load coupled to an output of the DA circuit, comprising: adjusting a resistance of a first programmable resistor coupled between a first portion of a secondary winding of a balun and an output, the secondary winding including a second portion coupled to ground, the balun including a primary winding coupled to a differential output of a driver amplifier (DA); and adjusting a resistance of a second programmable resistor coupled between the first portion and the second portion of the balun, wherein adjusting the resistances of the first and second programmable resistors includes setting a voltage standing wave ratio (VSWR) at the load.

Aspect 17: The method of aspect 16, wherein the load comprises a power amplifier (PA).

Aspect 18: The method of aspect 16 or 17, wherein adjusting the resistances of the first and second programmable resistors comprises adjusting the resistances based on an operating frequency band of the DA circuit.

Aspect 19: The method of any one of aspects 16-18, wherein adjusting the resistances of the first and second programmable resistors, comprises: adjusting the resistance of the first programmable resistor to be between a minimum resistance and a maximum resistance for the first programmable resistor; and adjusting the resistance of the second programmable resistor to a maximum resistance for the second programmable resistor.

Aspect 20: The method of any one of aspects 16-19, wherein adjusting the resistances of the first and second programmable resistors, comprises: adjusting the resistance of the first programmable resistor to the minimum resistance for the first programmable resistor; and adjusting the resistance of the second programmable resistor to be between a minimum resistance and the maximum resistance for the second programmable resistor.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a driver amplifier (DA) circuit, comprising:
a driver amplifier (DA) including a differential output;
a balun including a primary winding and a secondary winding, wherein the differential output of the DA is coupled to the primary winding of the balun, and wherein the secondary winding includes a first portion and a second portion, the second portion being coupled to ground;
a first programmable resistor coupled between the first portion of the secondary winding and an output of the DA circuit; and
a control circuit configured to adjust a resistance of the first programmable resistor to set a voltage standing wave ratio (VSWR) at a load coupled to the output of the DA circuit.

2. The apparatus of claim 1, wherein the control circuit is configured to adjust a resistance of the first programmable resistor to set the VSWR to within a range of two (2) or less.

3. The apparatus of claim 1, wherein the control circuit is configured to adjust the resistance of the first programmable resistor based on information regarding an operating frequency band of the DA circuit.

4. The apparatus of claim 1, further comprising a second programmable resistor coupled between the first portion and the second portion of the secondary winding of the balun.

5. The apparatus of claim 4, wherein the control circuit is configured to adjust a resistance of the second programmable resistor to set the VSWR.

6. The apparatus of claim 5, wherein the control circuit is configured to adjust the resistances of the first and second programmable resistors to set the VSWR.

7. The apparatus of claim 5, wherein the control circuit is configured to adjust the resistances of the first and second programmable resistors based on information regarding an operating frequency band of the DA circuit.

8. The apparatus of claim 5, wherein the control circuit is configured to adjust the resistance of the second programmable resistor to be greater than the resistance of the first programmable resistor.

9. The apparatus of claim 5, wherein, in a first configuration, the control circuit is configured to:
adjust the resistance of the first programmable resistor to be between a minimum resistance and a maximum resistance for the first programmable resistor; and
adjust the resistance of the second programmable resistor to a maximum resistance for the second programmable resistor.

10. The apparatus of claim 9, wherein, in a second configuration, the control circuit is configured to:
adjust the resistance of the first programmable resistor to the minimum resistance for the first programmable resistor; and
adjust the resistance of the second programmable resistor to be between a minimum resistance and the maximum resistance for the second programmable resistor.

11. The apparatus of claim 1, wherein the first programmable resistor comprises a set of switching devices coupled in parallel between the first portion of the secondary winding of the balun and the output of the DA circuit, wherein the control circuit is coupled to the set of switching devices.

12. The apparatus of claim 11, wherein the set of switching devices comprises a set of field effect transistors (FETs) including a set of drain/source terminals coupled to the first portion of the secondary winding of the balun, a set of source/drain terminals coupled to the output of the DA circuit, and a set of gate terminals coupled to the control circuit, respectively.

13. The apparatus of claim 12, wherein the set of switching devices comprises:
a first set of capacitors coupled between the set of drain/source terminals and the set of gate terminals of the set of FETs, respectively;
a second set of capacitors coupled between the set of source/drain terminals and the set of gate terminals of the set of FETs, respectively; and
a set of resistors coupled between the set of gate terminals and the control circuit, respectively.

14. The apparatus of claim 1, wherein the load comprises a power amplifier (PA).

15. The apparatus of claim 1, wherein the load has an impedance of substantially 50 Ohms.

16. A method for impedance matching a driver amplifier (DA) circuit to a load coupled to an output of the DA circuit, comprising:
adjusting a resistance of a first programmable resistor coupled between a first portion of a secondary winding of a balun and an output, the secondary winding including a second portion coupled to ground, the balun including a primary winding coupled to a differential output of a driver amplifier (DA); and
adjusting a resistance of a second programmable resistor coupled between the first portion and the second portion of the balun, wherein adjusting the resistances of the first and second programmable resistors includes setting a voltage standing wave ratio (VSWR) at the load.

17. The method of claim 16, wherein the load comprises a power amplifier (PA).

18. The method of claim 16, wherein adjusting the resistances of the first and second programmable resistors comprises adjusting the resistances based on an operating frequency band of the DA circuit.

19. The method of claim 16, wherein adjusting the resistances of the first and second programmable resistors, comprises:
adjusting the resistance of the first programmable resistor to be between a minimum resistance and a maximum resistance for the first programmable resistor; and
adjusting the resistance of the second programmable resistor to a maximum resistance for the second programmable resistor.

20. The method of claim 16, wherein adjusting the resistances of the first and second programmable resistors, comprises:
adjusting the resistance of the first programmable resistor to the minimum resistance for the first programmable resistor; and
adjusting the resistance of the second programmable resistor to be between a minimum resistance and the maximum resistance for the second programmable resistor.
